(19) United States
(12) Patent Application Publication
(10) Pub. No.: US 2013/0193402 A1
(43) Pub. Date: Aug. 1, 2013

(54) PHASE-CHANGE RANDOM ACCESS MEMORY DEVICE AND METHOD OF MANUFACTURING THE SAME

(71) Applicant: Choon Kun RYU, Icheon-si (KR)

(72) Inventor: Choon Kun RYU, Icheon-si (KR)

(21) Appl. No.: 13/482,240

(22) Filed: May 29, 2012

(30) Foreign Application Priority Data
Jan. 27, 2012 (KR) 10-2012-0008297

(51) Int. Cl. H01L 27/26; H01L 21/02

(52) U.S. Cl. 257/5; 438/381; 257/E27.002; 257/E21.003

(57) ABSTRACT

A phase-change random access memory (PCRAM) device and a method of manufacturing the same. The PCRAM device includes memory cells that each include a semiconductor substrate having a switching element, a lower electrode formed on the switching element, a phase-change layer formed on the lower electrode, and an upper electrode formed on the phase-change layer; and a porous insulating layer arranged to insulate one memory cell from another memory cell of the memory cells.

### CROSS-REFERENCES TO RELATED APPLICATION

The present application claims priority under 35 U.S.C. 119(a) to Korean application number 10-2012-0008297, filed on Jan. 27, 2012, in the Korean Patent Office, which is incorporated by reference in its entirety.

### BACKGROUND

1. Technical Field

The exemplary embodiments of the present invention relates to a nonvolatile memory device, and more particularly, to a phase-change random access memory (PCRAM) device and a method of manufacturing the same.

2. Related Art

With demands on lower power consumption of memory devices, memory devices having non-volatility and non-refresh properties have been researched. A PCRAM device, as one of the memory devices, applies a pulse to a phase-change layer which is a chalcogenide compound to store data using a difference between a resistance in an amorphous state and a resistance in a crystalline state.

In the PCRAM device, when a write current flows through a switching element and a lower electrode, Joule heat is generated at an interface between a phase-change layer and the lower electrode. The phase-change layer is phase-changed into an amorphous state or a crystalline state by the generated joule heat. Therefore, the PCRAM device stores data therein using a difference between resistances in the amorphous state and the crystalline state of the phase-change layer.

However, in the PCRAM device, the Joule heat generated when the write current flows may have an effect on a phase-change layer of adjacent cell as well.

Such phenomenon is generally referred to as thermal disturbance. The thermal disturbance may become a more serious in the high integration of a semiconductor memory device.

FIGS. 1A and 1B are views illustrating thermal disturbance of a PCRAM device.

As shown in FIGS. 1A and 1B, the PCRAM device includes a lower electrode 10 formed on a switching element (not shown), a phase-change layer 20 formed on the lower electrode 10, and an upper electrode 30 formed on the phase-change layer 20. The reference numeral 40 denotes an insulating layer.

As shown in FIG. 1A, if a cell A is written when cells B have been written with data “1”, that is, in a high resistance state, Joule heat generated at an interface between the lower electrode 10 and the phase-change layer 20 of the cell A is conducted to the cells B and thus phase-change material patterns of amorphous states in the cells B are crystallized so that resistances of the cells B are reduced, as shown in FIG. 1B.

The thermal disturbance generated in the PCRAM device causes malfunction thereof and thus reliability thereof is degraded.

### SUMMARY

One or more exemplary embodiments are provided to a PCRAM device and a method of manufacturing the same which are capable of increasing reliability of the PCRAM device by preventing thermal disturbance from being generated.

According to one aspect of an exemplary embodiment, there is a provided a PCRAM device. The PCRAM device may include: memory cells that each include a semiconductor substrate having a switching element, a lower electrode formed on the switching element, a phase-change layer formed on the lower electrode, and an upper electrode formed on the phase-change layer; and a porous insulating layer arranged to insulate one memory cell from another memory cell of the memory cells.

According to another aspect of an exemplary embodiment there is a provided a PCRAM device. The PCRAM device may include: a first lower electrode; a second lower electrode formed on the first lower electrode and have a smaller linewidth than the first electrode; a heat-resisting spacer formed on a sidewall of the second electrode; a phase-change layer formed on the second lower electrode and the heat-resisting spacer; and an upper electrode formed on the phase-change layer.

According to further aspect of an exemplary embodiment, there is a provided a method of manufacturing a PCRAM device. The method may include: forming a switching element on a semiconductor substrate; forming a porous insulating layer including a hole formed in a position corresponding to the switching element on the switching element; forming a lower electrode and a phase-change layer on the switching element; and forming an upper electrode on the phase-change layer.

These and other features, aspects, and embodiments are described below in the section entitled “DESCRIPTION OF EXEMPLARY EMBODIMENT”.

### BRIEF DESCRIPTION OF THE DRAWINGS

The above and other aspects, features and other is advantages of the subject matter of the present disclosure will be more clearly understood from the following detailed description taken in conjunction with the accompanying drawings, in which:

FIGS. 1A and 1B are views illustrating a thermal disturbance phenomenon in a PCRAM device;

FIG. 2 is a view illustrating a configuration of a PCRAM device according to an exemplary embodiment of the present invention; and

FIGS. 3A to 3F are views illustrating a method of manufacturing a PCRAM device according to an exemplary embodiment of the present invention.

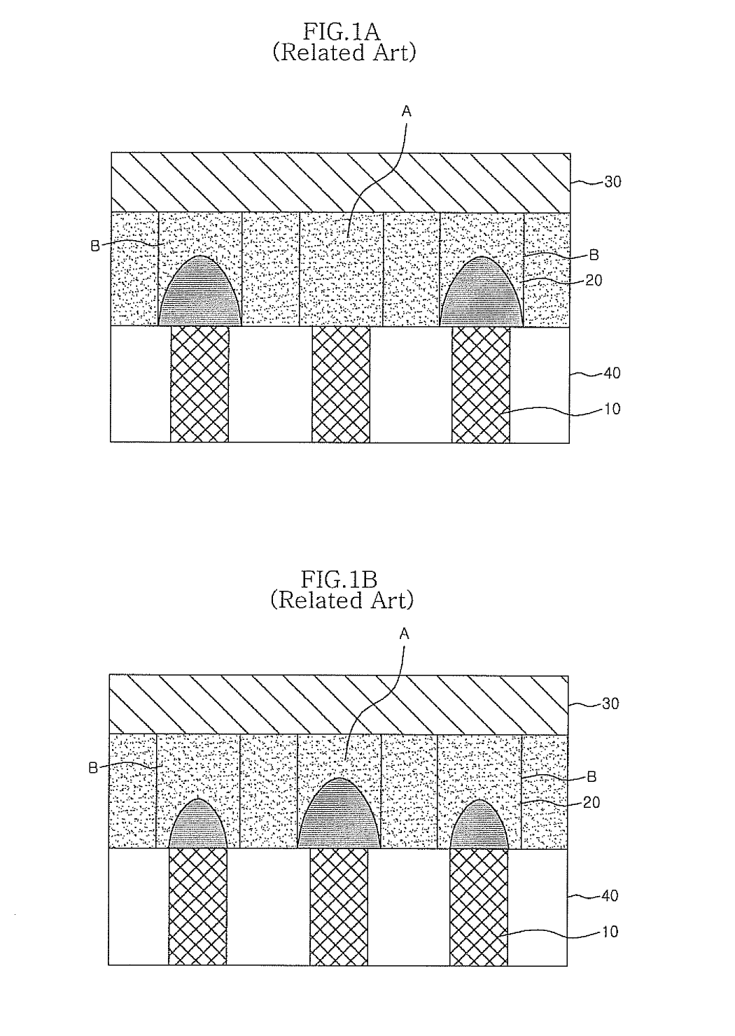

### DESCRIPTION OF EXEMPLARY EMBODIMENT

Hereinafter, exemplary embodiments will be described in greater detail with reference to the accompanying drawings.

Exemplary embodiments are described herein with reference to illustrations that are schematic illustrations of exemplary embodiments (and intermediate structures). As such, actual sizes and proportions of implemented exemplary embodiments may vary from the illustrated sizes and proportions. Further, exemplary embodiments should not be construed as limited to the particular shapes of regions illustrated herein but construed to include deviations in shapes that result from actual implementation. In the drawings, lengths and sizes of layers and regions may be exaggerated for clarity. Like reference numerals in the drawings denote like elements. It is also understood that when a layer is referred to as being “on” another layer or substrate, it can be directly on the other or substrate, or intervening layers may also be present.

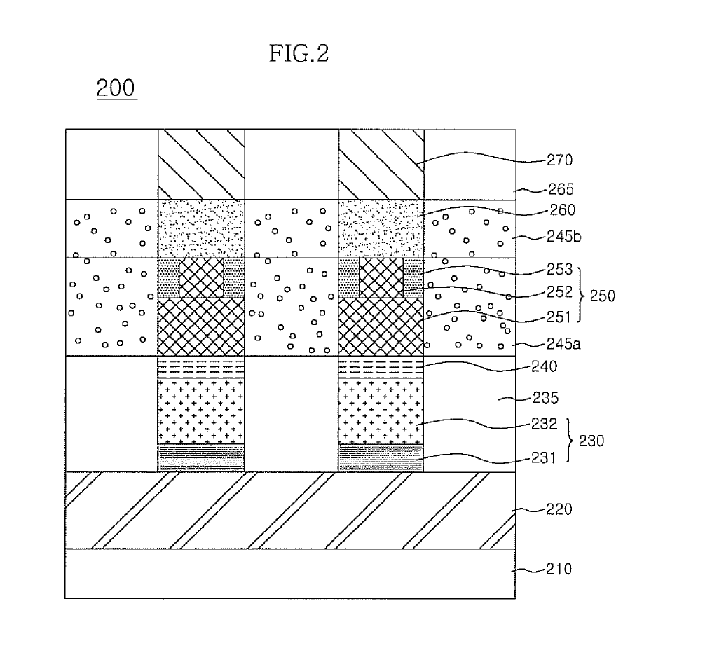

FIG. 2 is a view illustrating a configuration of a PCRAM device according to an exemplary embodiment of the present invention.

Referring to FIG. 2, in a PCRAM device 200 according to the exemplary embodiment, a word line region 220 including a metal layer or a metal nitride layer is formed on a semiconductor substrate 210.

A first insulating layer 235 including a hole for exposing a portion of the word line region 220 corresponding to each cell (not shown) is formed on the word line region 220 and a shottky diode 230 as a switching element is formed within the hole. The shottky diode 230 includes a barrier metal layer 231 which is in contact with the word line region 220 and a P+ polysilicon layer 232 formed on the barrier metal layer 231. Here, the shottky diode is formed as a switching element, but there is not limited thereto. A PN diode or a MOS transistor may be used as the switching element.

An ohmic contact layer 240 including metal silicide is formed on the shottky diode 230. Here, the ohmic contact layer 240 is formed to reinforce contact force between the shottky diode 230 and a lower electrode 250 to be formed later and may be omitted.

The lower electrode 250 and a phase-change layer 260 are formed on the ohmic contact layer 240. The lower electrode 250 includes a first electrode 251, a second electrode 252, and a heat-resisting spacer 253. The first electrode 251 is formed on the shottky diode 230 and includes tungsten (W). The second electrode 252 includes tungsten (W) and is formed on the first electrode 251 to be in contact with the phase-change layer 260. The second electrode 252 has a different linewidth from the first electrode 251.

The heat-resisting spacer 253 is formed on a sidewall of the second electrode 252 and has a heat-resistant property. Here, the second electrode 252 of the first electrode 251 and the second electrode 252, which is be in contact with the phase-change layer 260, may have a smaller linewidth than the first electrode 251. In the PCRAM device 200 according to the exemplary embodiment, porous insulating layers 245a and 245b having low thermal conductivity are deposited as an insulating layer which surrounds the lower electrode 250 and the phase-change layer 260 to absorb Joule heat generated at an interface between the lower electrode 250 and the phase-change layer 260. As the porous insulating layers 245a and 245b in the PCRAM device 200 according to the exemplary embodiment, a SiOCH insulating layer including nano-sized voids is formed by mixing alkyl silane gas with N₂O gas and applying RF power to the mixture gas in a plasma-enhanced chemical vapor deposition (PECVD) apparatus. The alkyl silane gas may include tri-methylsilane (SiH(CH₃)₃) or tetra-methylsilane (SiH(CH₃)₄).

An upper electrode 270 is formed on the phase-change layer 260. The reference numeral 265 denotes a second insulating layer.

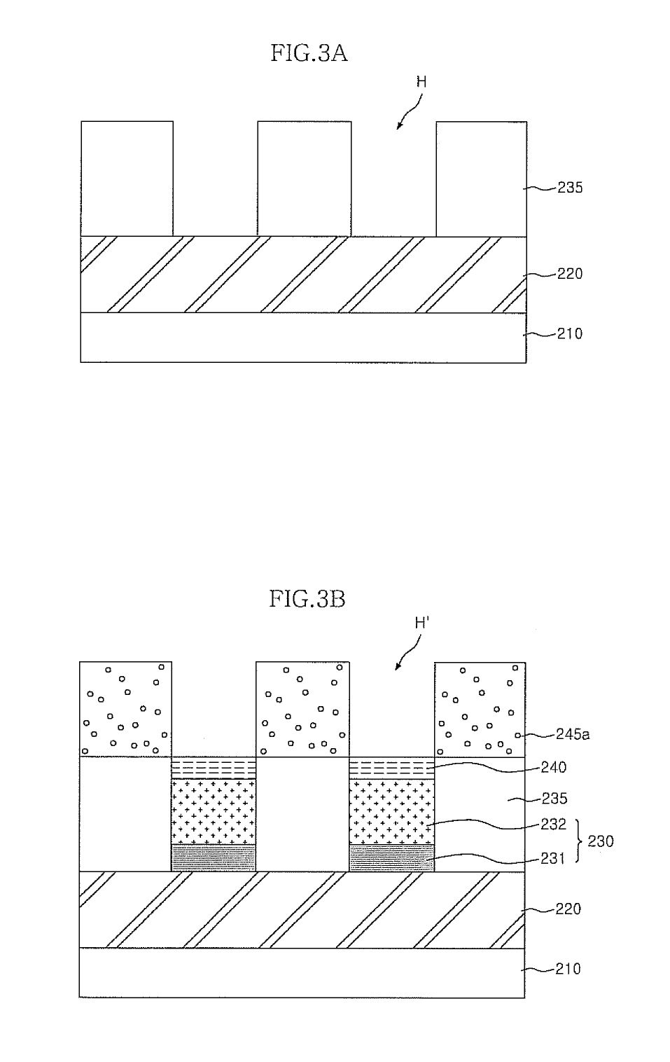

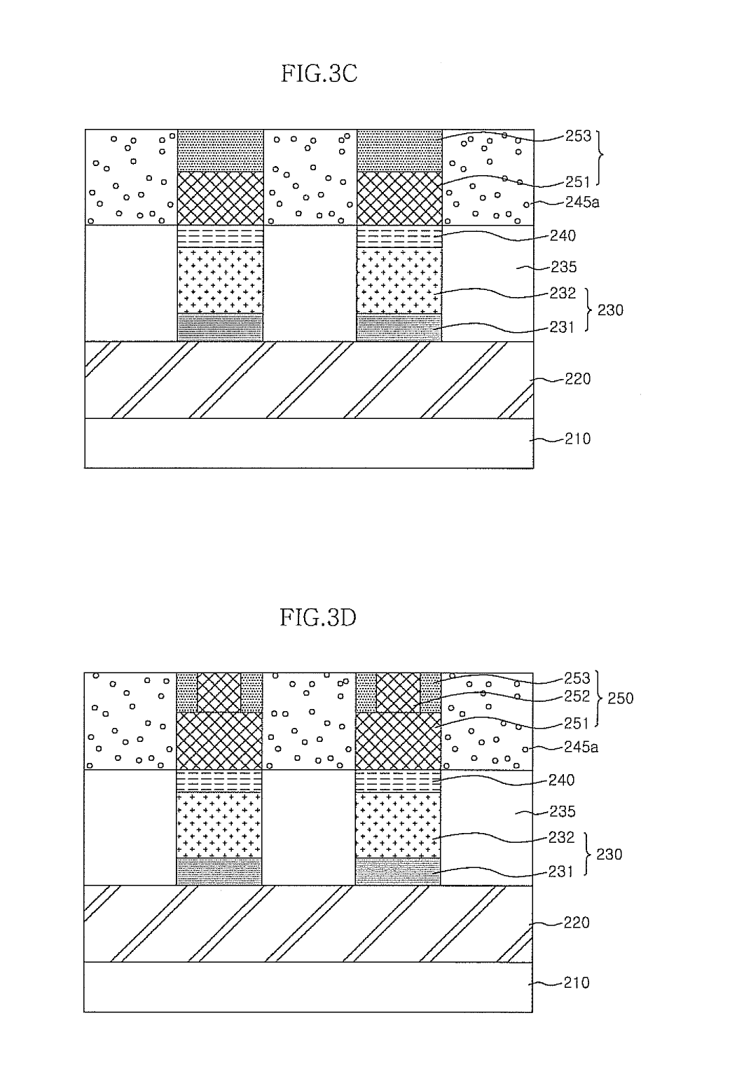

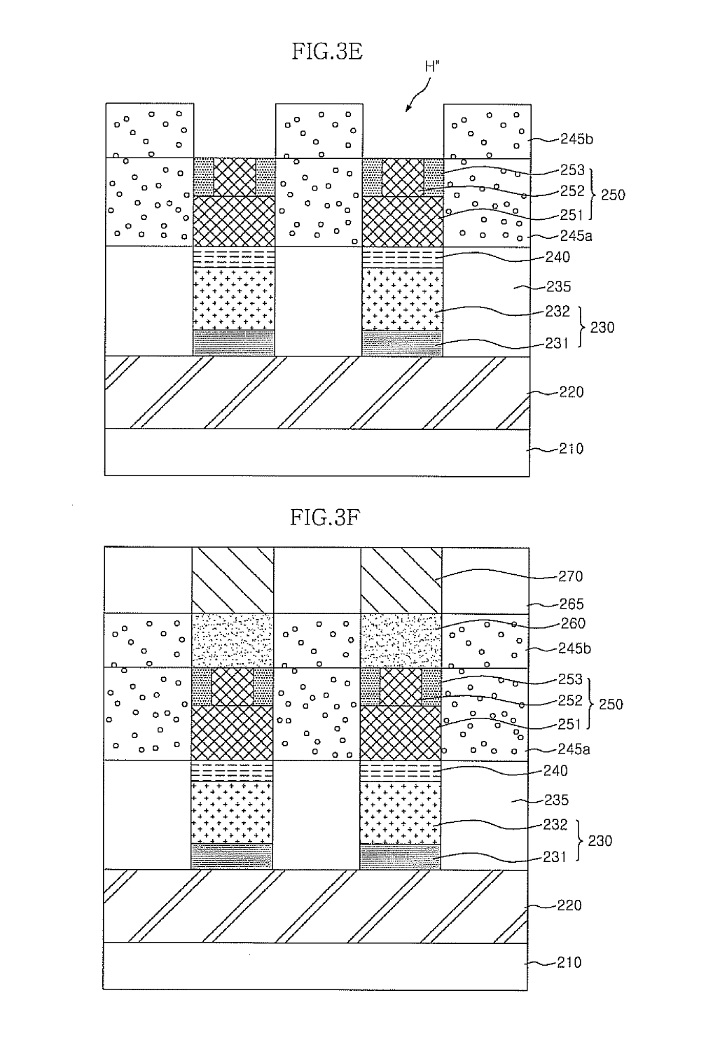

A method of manufacturing a PCRAM device according to an exemplary embodiment of the present invention will be described in detail with reference to FIGS. 3A to 3F.

FIGS. 3A to 3F are views illustrating a method of manufacturing a PCRAM device according to an exemplary embodiment of the present invention.

First, as shown in FIG. 3A, the method of manufacturing a PCRAM device 200 include forming a word line region 220 including a metal layer or a metal nitride layer on a provided semiconductor substrate 210.

A first insulating layer 235 including a nitride layer or an oxide layer is formed on the word line region 220 and then etched using a dry etching process to expose the word line region 220 corresponding to each cell, thereby forming a plurality of holes H.

As shown in FIG. 3B, a barrier metal layer 231 is deposited on a bottom portion of each of the plurality of holes H and a P+polysilicon layer 232 is deposited on the barrier metal layer 231. Thereby, a shottky diode 230 buried within each hole H is formed.

A transition metal layer (not shown) is deposited on a resultant structure of the semiconductor substrate 210 and then a selective thermal treatment is performed on the transition metal layer to form an ohmic contact layer 240 including metal silicide.

A first porous insulating layer 245a having low thermal conductivity is deposited on the ohmic contact layer 240 and then etched by a dry etching process to expose the ohmic contact layer 240, thereby forming a plurality of holes H′. At this time, as the first porous insulating layer 245a, a SiOCH insulating layer including nano-sized voids is formed by mixing a alkyl silane gas such as tri-methylsilane (SiH(CH₃)₃) or tetra-methylsilane (SiH(CH₃)₄) with N₂O gas and applying RF power to the mixture gas. To form the first porous insulating layer 245a of the PCRAM device 200 according to the exemplary embodiment, a flow rate of the alkyl silane gas may be in a range of 200 sccm to 1000 sccm and a flow rate of the N₂O gas which is a reaction gas of the alkyl silane gas may be in a range of 1000 sccm to 5000 sccm. In addition, the RF power applied to the supplied alkyl silane gas and the N₂O gas may be in a range of 500 W to 2000 W and a deposition temperature may be in a range of 300° C. to 400° C. In the first porous insulating layer 245a formed in the above-described process environment, voids substantially having a size in a range of 1 nm to 10 nm are included.

As shown in FIG. 3C, tungsten (W) is deposited in the plurality of holes H′, isolated from each other using a chemical mechanical polishing (CMP) process, and recessed by a dry etching process so that a first electrode 251 is formed in each of the plurality of holes H′.

A silicon nitride layer 253 having a heat-resistant property is deposited on the first electrode 251.

As shown in FIG. 3D, the silicon nitride layer 253 is etched by a dry etching process so that the silicon nitride layer 253 remains on a sidewall of each of the plurality of holes H′ and the first electrode 251 is exposed. Tungsten (W) is deposited in a space of each hole H′ from which the silicon nitride layer 253 is removed and isolated from each other by a CMP process, thereby forming a second electrode 252 of the lower electrode 250. Although the first electrode 251 and the second electrode 252 include W, there is not limited thereto. In addition to a metal material such as W, each of the first electrode 251 and the second electrode 252 may include at least one selected from the group consisting of an alloy, a metal oxynitride layer, an oxide electrode, and a conductive carbon compound. For example, each of the first electrode 251 and the second electrode 252 may include at least one selected from the group consisting of titanium nitride (TiN), tantalum nitride (TaN), tungsten nitride (WN), molybdenum nitride (MoN), niobium nitride (NbN), titanium silicon nitride (TiSiN), titanium aluminum nitride (TiAlN), titanium boron nitride (TiBN), zirconium silicon nitride (ZrSiN), tungsten silicon nitride (WSiN), tungsten boron nitride (WBN), zirconium aluminum nitride (ZrAlN), molybdenum silicon nitride (MoSiN), molybdenum aluminum nitride (MoAlN), tantalum silicon nitride (TaSiN), tantalum aluminum nitride (TaAlN), titanium (Ti), molybdenum (Mo), tantalum (Ta), platinum (Pt), titanium silicide (TiSi), tantalum silicide (TaSi), titanium tungsten (TiW), titanium oxynitride (TiON), titanium aluminum oxynitride (TiAlON), tungsten oxynitride (WON), tantalum oxynitride (TaON), and iridium oxide (IrO2). In the PCRAM device 200 according to the exemplary embodiment, Joule heat generated between the second electrode 252 and a phase-change layer (260 in FIG. 3F) to be formed later is prevented from being conducted by the silicon nitride layer 253 having a heat-resistant property and serving as a heat-resisting spacer and further by the first porous insulating layer 245a and a second porous insulating layer (245b in FIG. 3E) formed to surround the lower electrode 250 and the phase-change layer 260. Therefore, the occurrence of the thermal disturbance between adjacent cells is prevented.

As shown in FIG. 3E, a second porous insulating layer 245b is deposited on the lower electrode 250 by the same deposition method and in the same deposition environment as the first porous insulating layer 245a. Then, the second porous insulating layer 245b is etched by a dry etching process to expose the lower electrode 250, thereby forming a plurality of holes H″.

As shown in FIG. 3F, a phase-change material, for example, germanium-antimony-tellurium (GeSbTe) is deposited through a chemical vapor deposition (CVD) method and then planarized by a CMP process, thereby forming the phase-change layer 260.

A second insulating layer 265 including an oxide layer or a nitride layer is formed on the phase-change layer 260 and the second porous insulating layer 245b and etched by a dry etching process to expose the phase-change layer 260. Then, an upper electrode 270 is formed on the phase-change layer 260.

The PCRAM device 200 according to the exemplary embodiment modifies an insulating layer for the lower electrode 250 and the phase-change layer 260 and thus prevents the occurrence of thermal disturbance so that reliability thereof is increased.

The above-described exemplary embodiments are exemplary only, the present invention should include all embodiments consistent with the exemplary features as described above and in the accompanying drawings and claims.

What is claimed is:

1. A phase-change random access memory (PCRAM) device, comprising:
memory cells that each include a semiconductor substrate having a switching element, a lower electrode formed on the switching element, a phase-change layer formed on the lower electrode, and an upper electrode formed on the phase-change layer; and
a porous insulating layer arranged to insulate one memory cell from another memory cell of the memory cells.

2. The PCRAM device of claim 1, wherein the porous insulating layer surrounds the lower electrode and the phase-change layer.

3. The PCRAM device of claim 2, wherein the porous insulating layer includes SiOCH.

4. The PCRAM device of claim 3, wherein the porous insulating layer includes nano-sized voids by mixture of alkyl silane gas and N₂O gas and application of radio frequency (RF) power to the mixture gas.

5. The PCRAM device of claim 4, wherein the alkyl silane gas includes tri-methylsilane (SiH(CH₃)₃) or tetra-methylsilane (SiH(CH₃)₄).

6. The PCRAM device of claim 4, wherein the voids included in the porous insulating layer have a size in a range of 1 nm to 10 nm.

7. The PCRAM device of claim 1, wherein the lower electrode includes:
a first electrode formed on the switching element;
a second electrode formed on the first electrode and having a smaller linewidth than the first electrode; and
a heat-resisting spacer having a heat-resistant property and formed on a sidewall of the second electrode.

8. A phase-change random access memory (PCRAM) device, comprising:
a first lower electrode;
a second lower electrode formed on the first lower electrode and have a smaller linewidth than the first electrode;
a heat-resisting spacer formed on a sidewall of the second electrode;
a phase-change layer formed on the second lower electrode and the heat-resisting spacer; and
an upper electrode formed on the phase-change layer.

9. The PCRAM device of claim 8, wherein the heat-resisting spacer includes a silicon nitride layer.

10. The PCRAM device of claim 8, further comprising a porous insulating layer having voids and surrounding the first and second lower electrodes and the phase-change layer.

11. The PCRAM device of claim 10, wherein the porous insulating layer includes a SiOCH layer having nano-sized voids in a range of 1 nm to 10 nm.

12. A method of manufacturing a phase-change random access memory (PCRAM) device, the method comprising:
forming a switching element on a semiconductor substrate;
forming a porous insulating layer including a hole formed in a position corresponding to the switching element on the switching element;
forming a lower electrode and a phase-change layer on the switching element; and
forming an upper electrode on the phase-change layer.

13. The method of claim 12, wherein the forming of the porous insulating layer includes depositing a SiOCH layer including nano-sized voids by mixing alkyl silane gas with N₂O gas and applying radio frequency (RF) power to the mixture gas.

14. The method of claim 13, wherein the alkyl silane gas includes tri-methylsilane (SiH(CH₃)₃) or tetra-methylsilane (SiH(CH₃)₄).

15. The method of claim 14, wherein a flow rate of the alkyl silane gas is in a range of 200 sccm to 1000 sccm.

16. The method of claim 13, wherein a flow rate of the N₂O gas is in a range of 1000 sccm to 5000 sccm.

17. The method of claim 13, wherein the RF power is in a range of 500 W to 2000 W.

18. The method of claim 13, wherein a deposition temperature of the porous insulating layer is in a range of 300° C. to 400° C.

19. The method of claim 13, wherein the voids included in the porous insulating layer have a size in a range of 1 nm to 10 nm.

20. The method of claim 12, wherein the forming of the lower electrode includes:
forming a first lower electrode on the switching element; and
forming a second lower electrode having a smaller linewidth than the first lower electrode on the first lower electrode.

21. The method of claim 20, wherein the forming of the second lower electrode includes:
deposing a silicon nitride layer on the first electrode;
etching the silicon nitride layer to expose the first lower electrode at the center of the hole; and
deposing the second lower electrode on the exposed first lower electrode.
